(19) United States
(12) Patent Application Publication
(10) Pub. No.: US 2013/0070795 A1
(43) Pub. Date: Mar. 21, 2013

(54) METHOD TO SWITCH EMISSION WAVELENGTH OF TUNABLE LASER DIODE

(71) Applicants: Tomoko IKAGAWA, Yokohama-shi (JP); Keiji TANAKA, Yokohama-shi (JP)

(72) Inventors: Tomoko IKAGAWA, Yokohama-shi (JP); Keiji TANAKA, Yokohama-shi (JP)

(73) Assignee: SUMITOMO ELECTRIC INDUSTRIES, LTD., Osaka-shi (JP)

(21) Appl. No.: 13/615,086

(22) Filed: Sep. 13, 2012

(30) Foreign Application Priority Data
Sep. 16, 2011 (JP) 2011-203445
Jul. 4, 2012 (JP) 2012-150593

(51) Int. Cl. H01S 5/06

(52) U.S. Cl. 372/20

(57) ABSTRACT

The method to change the emission wavelength of a tunable LD is disclosed. In an ordinary state, the method monitors conditions not only relating to determine the emission wavelength but conditions independent of the emission wavelength by an ordinary A/D-C implemented within the controller. Responding to an instruction to switch the emission wavelength, the controller only monitors the former conditions affecting the determination of the emission wavelength. The sampling rate of the ordinary A/D-C is equivalently enhanced without installing an additional A/D-C.

### BACKGROUND OF THE INVENTION

1. Field of the Invention

The present invention relates to a sequence to control a tunable laser diode (hereafter denoted as LD).

2. Related Background Arts

As the wavelength division multiplexing (hereafter denoted as WDM) system has been developed, a wavelength tunable LD has become important. One type of the tunable LDs provides two regions, one of which is a gain region and the other is a region for selecting an emission wavelength thereof. A Conventional tunable LD selects the emission wavelength thereof by adjusting a temperature thereof with a thermo-electric cooler (hereafter denoted as TEC) to modify the refractive index of the latter region. For such an LD with a complicated configuration, a well-regulated sequence is necessary to switch the emission wavelength thereof promptly from one grid wavelength to another one, for instance, within a several decades of milli-second.

### SUMMARY OF THE INVENTION

The present application relates to a method to control an emission wavelength of a tunable LD that includes a reflective portion and a gain portion. The reflective portion shows a plurality of reflection peaks whose peak wavelengths are varied by stimulated conditions applied thereto, while, the gain portion shows a plurality of gain peaks whose peak wavelengths are also stimulated conditions applied thereto. The tunable LD emits light with the wavelength at which one of the reflection peaks coincides with one of the gain peaks. The method includes steps of: regularly monitoring conditions of the reflective portion, the gain portion, and ambient conditions of the tunable LD; receiving an external instruction to switch the emission wavelength; and, triggered by the external instruction, monitoring the conditions only of the reflective portion and the gain portion that affect the emission wavelength.

Because the ambient conditions not affecting the emission wavelength are omitted to be monitored after the reception of the external instruction, the new emission wavelength is promptly switched and stable even if the method implements only one analog-to-digital converter (A/D-C). The sampling period for the conditions affecting the emission wavelength is equivalently enhanced.

In another configuration, the method may monitor, after the reception of the external instruction, conditions of the reflective portion and the gain portion regularly, but the ambient conditions intermittently. Even such a sequence, the sampling period for the conditions affecting the emission wavelength is equivalently enhanced.

The reflective portion includes a heater to modify the refractive index thereof thermally, while, the gain portion includes a tune region whose refractive index is electrically modified by the current injected therein. The conditions to be monitored after the reception of the external instruction are the electrical power supplied to the heater in the reflective portion and the current injected into the tune region.

In another embodiment of the invention, the reflective portion includes a heater to modify the refractive index thereof thermally, while, gain portion includes a tune region with a heater to modify the refractive index thereof thermally. The conditions to be monitored after the reception of the external instruction are the electrical power supplied to the heater in the reflective portion and the electrical power to the heater in the tune region.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 schematically illustrates a fundamental arrangement of an apparatus to control a tunable LD according to an embodiment of the present invention;

FIG. 2 is a flow chart to switch a control mode according to an embodiment of the invention;

FIGS. 3A to 3C show orders of conditions to be monitored by the controller in respective modes; and

FIG. 4 schematically illustrates a fundamental arrangement of an apparatus to control another type of a tunable LD.

### DESCRIPTION OF PREFERRED EMBODIMENTS

Next, some preferred embodiments according to the present invention will be described as referring to drawings. In the description of the drawings, numerals or symbols same or similar to each other refer to elements same or similar to each other without overlapping explanations.

### First Embodiment

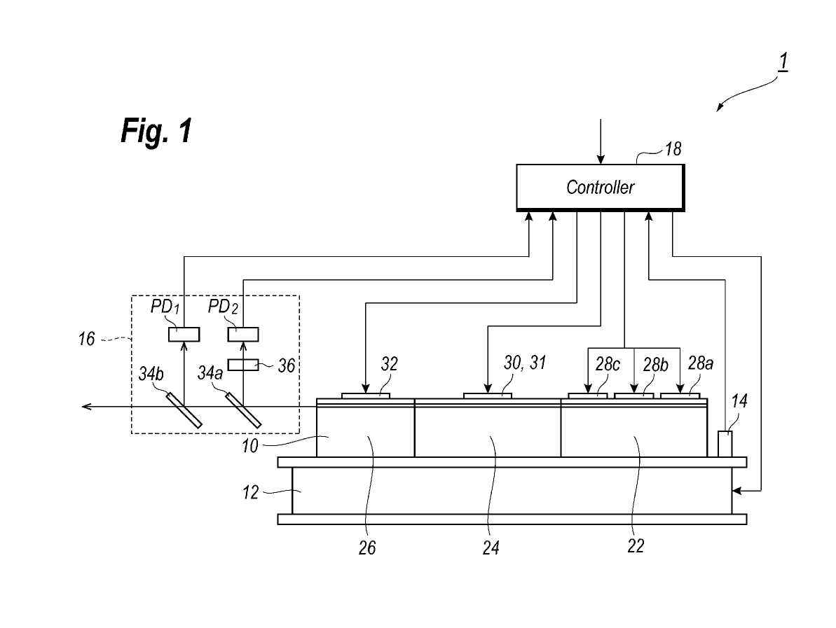

FIG. 1 schematically illustrates an apparatus of a tunable LD with an intelligent controller according to the first embodiment of the invention. The apparatus 1 shown in FIG. 1 includes a TEC 12 that mounts the tunable LD 10 thereon, a temperature sensor 14, usually a thermistor, to sense a temperature of the tunable LD 10 indirectly, a wavelength locker 16 to lock an emission wavelength of the tunable LD 10, and a controller 18 to control the operation of the tunable LD 10 comprehensively.

The wavelength locker 16 includes two photodiodes (PDs), PD₁ and PD₂, the former of which PD₁ receives the optical beam output from the tunable LD 10 via two beam splitters, 34a and 34b, while, the other PD₂ also receives the output beam from the tunable LD 10 via the only one of the beam splitter 34a but a etalon filter 36. The PDs, PD₁ and PD₂ provide electrical outputs to the controller 18.

The controller 18 includes a central processing unit (CPU), memories such as a random access memory (RAM) and a read only memory (ROM), a power supply, and some monitoring section including analog-to-digital converters (A/D-C). Portion or all functions of the controller 18 may be implemented by, for instance, a field programmable gate array (FPGA), application specific integrated circuit (ASIC), and so on. Memories within the controller 18 includes a look-up-table (LUT) that stores initial conditions to set the emission wavelength of the tunable LD 10 in a target wavelength. The controller 10 outputs various parameters to respective portions, 22 to 26, of the tunable LD 10 via the electrodes, 28a to 28c, and 30 to 33.

Next, details of the tunable LD 10 will be described. The tunable LD 10 of the embodiment includes a Chirped Sampled Grating Distributed Bragg Reflector (hereafter denoted as CSG-DBR) 22 as a reflective portion, a Sampled Grating Distributed Feedback (hereafter denoted as SG-DFB) 24 as a gain portion, and a Semiconductor Optical Amplifier (SOA) 26. Former two portions, CSG-DBR 22 and SG-DFB 24, may tune the emission wavelength of the LD 10.

The CSG-DBR 22 includes a waveguide that has a plurality of gratings each apart by a predetermined distance; accordingly, whose reflectance spectrum shows a plurality of peaks each apart by a preset and substantially constant span. This span between the reflectance peaks is slightly different from the span of the gain peaks attributed to the SG-DFB 24, which will be described in detail later. Then, the tunable LD 10 may emit light with a wavelength at which one of the reflectance peaks of the CSG-DBR 22 and one of the gain peaks of the SG-DFB 24 coincide to each other. The CSG-DBR 22 may include a plurality of heaters, three heaters in the present embodiment, integrally formed on the surface of the CSG-DBR 22. Adjusting the power supplied to respective heaters via the electrodes, 28a to 28c, which modifies the refractive index of the waveguide thermally, the reflectance spectrum of the CSG-DBR 22, especially the span between the reflection peaks, may be modified, which may finely tune the emission wavelength of the tunable LD 10. The TEC 12, which may change the temperature of the tunable LD 10, may also tune the reflectance spectrum of the CSG-DBR 22.

The SG-DFB 24 provides a waveguide with a plurality of gratings each apart by a preset span. The waveguide in the SG-DFB 24 may be divided into two regions, one of which is called as the gain region, while, the other is called as the tune region. The SG-DFB 24 thus configured shows a gain spectrum with a plurality of gain peaks. The gain regions and the tune regions have respective electrodes, 30 and 31, the former of which inject the driving current to generate photons in the waveguide, while, the other also inject the current but to modify the refractive index of the waveguide electrically to modify the span between the gain peaks. The gain spectrum of the CSG-DFB 24 maybe also varied by changing the temperature of the LD 10 by the TEC 12.

The SOA 26 also includes a waveguide and an electrode 32. The waveguide therein optically couples with the waveguide in the SG-DFB 24 and that in the CSG-DBR 22. Injecting the carriers into the waveguide via the electrode 32, the optical gain of the waveguide in the SOA 26 is changed, and the amplification factor of the SOA 26 may be adjusted. The tunable LD 10 of the embodiment thus configured may tune the emission wavelength thereof promptly by adjusting the electrical power to the heaters and the current injected in the tune regions as the temperature of the LD 10 is substantially constant by the TEC 12.

Next, a sequence to tune the emission wavelength by the controller 18 is explained. Starting the operation of the apparatus 1, the controller 18 first sets the temperature of the tunable LD 10 to a target temperature by feed backing the sensed information through the temperature sensor 14 to the TEC 12. After the temperature becomes stable in the target temperature, the controller 18 activates the LD 10 by setting parameters corresponding to the target wavelength, where the parameters include the bias current I_{LD}_{_{—}}_{INI} in the gain region, the current to the SOA 26 I_{SCA}_{_{—}}_{INI}, the current to heaters, I_{HT1}_{_{—}}_{INI} to I_{HT3}_{_{—}}_{INI}, and the current to the tune region, I_{TUNE}_{_{—}}_{INI}. Setting the initial currents above, the emission wavelength of the tunable LD 10 becomes close to the target wavelength, and the ratio of the photocurrents I_{PD2}/I_{PD1} each output from the PDs, PD₁ and PD₂ becomes also close to the target value.

Then, the controller 18 stabilizes the electrical power supplied to the heaters in the CSG-DBR 22 to make the reflection spectrum of the CSG-DBR 22 in stable. Just after setting the the initial conditions, the heater currents are set in I_{HTX}_{_{—}}_{INI} (X=1 to 3), then the electrical power to the heaters P_{HTX}_{_{—}}_{INI} are calculated by:

P_{HTX}_{_{—}}_{INI}=I_{HTX}_{_{—}}_{INI}×V_{HTX}_{_{—}}_{INI}

V_{HTX}_{_{—}}_{INI}=I_{HTX}_{_{—}}_{INI}×R_{HTX}_{_{—}}_{INI}.

The initial currents I_{HTX}_{_{—}}_{INI} is evaluated beforehand and set in the LUT such that the initial electrical powers supplied to the heaters P_{HTX}_{_{—}}_{INI} are equal to the target power P_{HTX}_{_{—}}_{T}. In equations above, V_{HTX}_{_{—}}_{INI} and R_{HTX}_{_{—}}_{INI} are the voltage applied to respective heaters, and resistance thereof. The controller 18, in order to keep the electrical power supplied to the heaters, calculates the power P_{HTX} currently given to the heaters by the initial current I_{HTX}_{_{—}}_{INI} and the voltage V_{HTX} sensed through the A/D-C, evaluates a shift of the current electrical power P_{HTX} from the target power P_{HTX}_{_{—}}_{T}, and compensates the shift by adjusting the current I_{HTX}. The controller performs the operation above described for the heaters individually. Respective heaters provide two electrodes, one of which operates as a ground electrode to be common to all heaters. When a large current flows in the heater, the parasitic resistance of the common electrode sometimes raises the ground level. Accordingly, the controller 18 monitors the ground level in addition to currently applied to the electrodes 28a to 28c, and calculates the currently applied voltage V_{HTX} to the heaters by removing the ground level.

The controller 18 adjusts the optical output power of the tunable LD 10 to be equal to the target power by adjusting the injection current to the SOA 26 such that the photocurrent I_{PD1} of the PD₁ becomes equal to a target one. Furthermore, the controller 18 performs the fine tuning of the emission wavelength. Specifically, the controller 18 adjusts the injection current to the tune region and the electrical power supplied to the heaters such that the ratio of the photocurrents IPD₂/IPD₁ coincides with the target one.

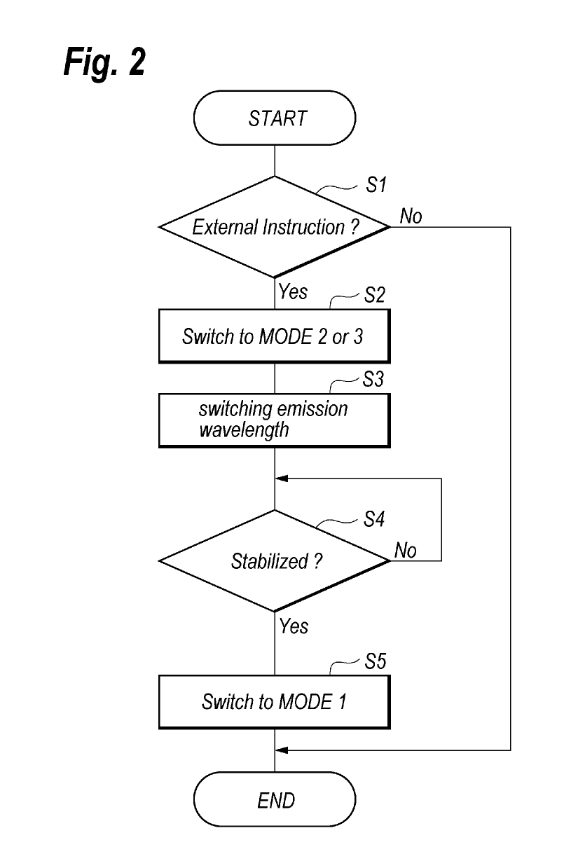

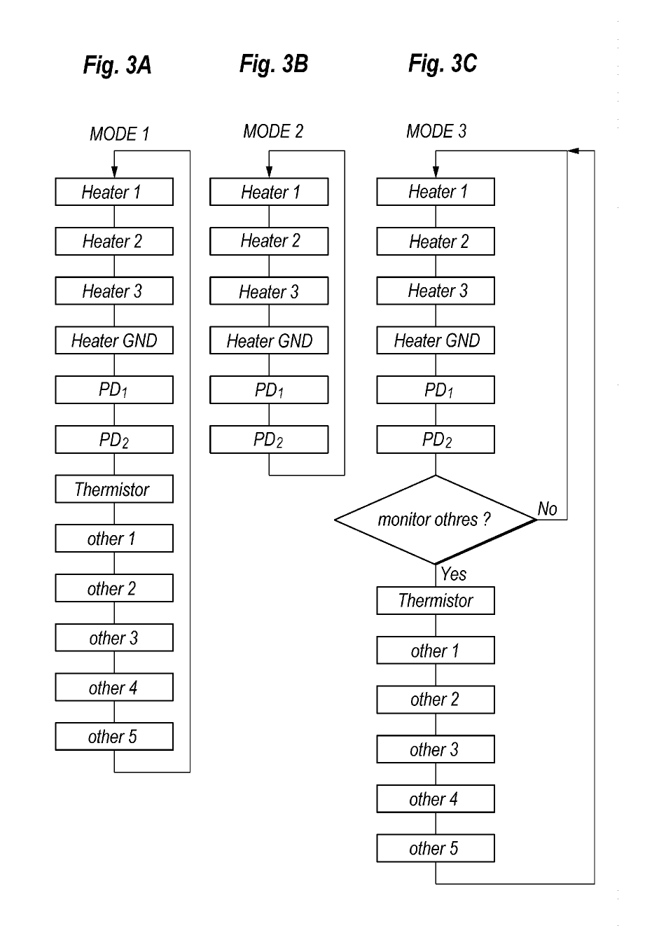

The controller 18 monitors all conditions of the tunable LD 10, such as the ground level, the heater bias, the photocurrents of the PDs, PD₁ and PD₂, the temperature of the TEC 12, and so on, via A/D-Cs implemented with the controller 18. Because of a restricted size of the controller 18, the number of A/D-Cs is limited. The controller 18 of the present embodiment implements two A/D-Cs, and switches the monitoring mode to monitor the parameters above mentioned. FIG. 2 shows the sequence to change the mode for the A/D-C, while, FIG. 3 shows the turn of the monitoring in respective modes.

The sequence to change the mode, which is shown in FIG. 2, is regularly iterated after the apparatus 1 is activated.

Specifically, starting the apparatus 1, the controller 18 regularly checks whether the instruction to change the emission wavelength is asserted or not at step S1. When the instruction is asserted, the controller 18 switches the sensing mode to the mode 2 or the mode 3, where only the conditions affecting the emission wavelength and sometimes the optical output power are monitored at step S2, which equivalently increases the sampling rate of the A/D-C. In addition, when the optical output is activated, the controller 18 sets the tunable LD 10 inactive by adjusting primarily the injection current to the SOA 26. Then, responding to the external instruction to switch to a new emission wavelength, the controller 18 reads the new initial parameters from the LUT, sets them to the tunable LD 10 and the TEC 12, and performs the initial tuning (rough tuning) and the fine tuning of the emission wavelength by adjusting the electrical power supplied to the heaters in the CSG-DBR 22 and the tuning current injected into the tune region of the SG-DFB 24 at step S0. Verifying the emission wavelength and the optical output power at step S4, the sequence returns the fine tuning when the emission wavelength and the optical output power are still slightly off from respective target values, while, advances to step S5 to recover the sensing mode 1 when the emission wavelength and the optical output power become in a preset range around respective target values.

As indicated in FIG. 3A, the sensing mode 1 monitors all conditions to be monitored evenly, where Heater_1, Heater_2, and Heater_3 are voltages of the electrodes each corresponding to respective heaters, while, Heater_GND is a voltage of the ground level. Also, “PD₁” and “PD₂” are to monitor the photocurrents of respective PDs, PD₁ and PD₂. “Thermistor” is to monitor the temperature of the TEC 12 via the thermistor 14, while, “other_1” to “other_5” correspond to the ambient conditions which are not relating to adjust the emission wavelength and the optical output power, such as, a voltage of the power supply V_{CC} of the apparatus 1, the bias voltage to the SOA 26, bias voltages to the gain region and the tune region of the SG-DFB 24, the supply current to the TEC 12, and so on.

On the other hand, the sensing mode 2 shown in FIG. 3B only senses voltages of the heaters, “Heater_1”, “Heater_2”, “Heater_3”, and “Heater_GND”; and the photocurrents, “PD₁” and “PD₂”. A limited monitoring in the mode 2 may accelerate the sampling period by the A/D-C without increasing the clock frequency thereof. That is, the sensing mode 1 in FIG. 3A monitors at least 12 conditions, namely, 6 conditions for the adjustment of the emission wavelength and the optical output power, and rest 6 conditions not relating thereto. While, the sensing mode 2 only monitors the former 6 conditions, which may accelerate the sampling period at least twice as that of the sensing mode 1.

The controller 18 may change the sensing mode from the mode 1 to the mode 3 shown in FIG. 3C instead of the mode 2. In the mode 3, the sampling rate for the conditions directly related to adjust the emission wavelength and the optical output power is different from the rate for monitoring rest conditions independent of the adjustment of the emission wavelength and the optical output power. Specifically, the first group of the conditions relating to adjust the emission wavelength and the output power are monitored regularly, while, the rest conditions are monitored intermittently. Thus, the sampling rate for the first group of the conditions maybe equivalently enhanced to make the response of the apparatus 1 faster.

The sequence thus described to control the tunable LD 10 makes the emission wavelength and the optical output power thereof in stable by adjusting the electrical power supplied to the heaters in the CSG-DBR 22, the injection current supplied to the SG-DFB 24, and that to the SOA 26 based on the monitored parameters of the electrical power to the heaters, the output of the PDs, PD₁ and PD₂, and the operating temperature of the tunable LD 10. When an external instruction triggers to switch the emission wavelength from one grid to another grid of the WDM system, only the conditions affecting the emission wavelength and the optical output power of the tunable LD 10 are monitored to make the response to switch the emission wavelength faster. Even in such sensing modes, conditions necessary to adjust the emission wavelength and the optical output power are regularly monitored; the stability of the emission wavelength and the optical output power of the tunable LD are precisely kept substantially in constant. Thus, the sequence of the present embodiment makes it possible to accelerate the change of the emission wavelength as keeping the preset optical output power without increasing the power consumption and the circuit size of the apparatus by installing additional A/D-Cs or faster A/D-Cs.

The response of the emission wavelength of an LD against the change of the operating temperature is generally slower than that against the current injection to the tune region or the supply of the electrical power to the heaters. Then, in an ordinary state after the operating temperature becomes stable, the adjustment of the emission wavelength and the optical output power may be carried out with relatively slower sequence. While, at the time to switch the emission wavelength, the injection current newly supplied to the SOA 26, that supplied to the tune region of the SG-DFB 24, and that supplied to the heaters in the CSG-DBR 22, where they are inevitably changed by the instruction to switch the emission wavelength, affect the temperature distribution of the tunable LD to set the emission wavelength instable. In order to switch the emission wavelength and the optical output power to the new target wavelength and the output power within several decades of milli-second, the response of the control is necessary to be enhanced.

Factors to determine the response of the feedback loop by the digital processing are follows:
(1) response of the physical phenomenon;
(2) sampling rate by the A/D-C; and
(3) calculating time.
   As for the first factor, the present embodiment of the tunable LD 10 monolithically integrates the heaters with the waveguide in the CSG-DBR 22; then, the thermal response from the supplement of the new electric power to the heaters to the shift of the emission wavelength is several micro-seconds at most. For the third factor, the algorithm to calculate the new conditions do not use complicated procedures, then, the time to estimate new conditions is enough faster than the second factor. Thus, the sampling rate of the A/D-C primarily and almost solely determines the response of the control. Enhancing the sampling rate of the A/D-C, the switch of the emission wavelength to a new condition and the stabilization of the optical output power may be quickly completed. The controller 18 conventionally implements a single A/D-C to monitor various conditions of the apparatus. In order to increase the sampling rate of the A/D-C, an additional high-speed A/D-C or a plurality of A/D-Cs is necessary to enhance the equivalent sampling rate. However, such an arrangement always accompanies with the increase of the power consumption and the size of the circuit.

According to the embodiment of the present invention thus described, the controller 18 changes the sensing mode of the A/D-C between the mode 1 and the modes, 2 and 3, which equivalently enhances the sampling rate of the A/D-C without installing any other A/D-Cs and the switch of the emission wavelength of the tunable LD is accelerated.

### Second Embodiment

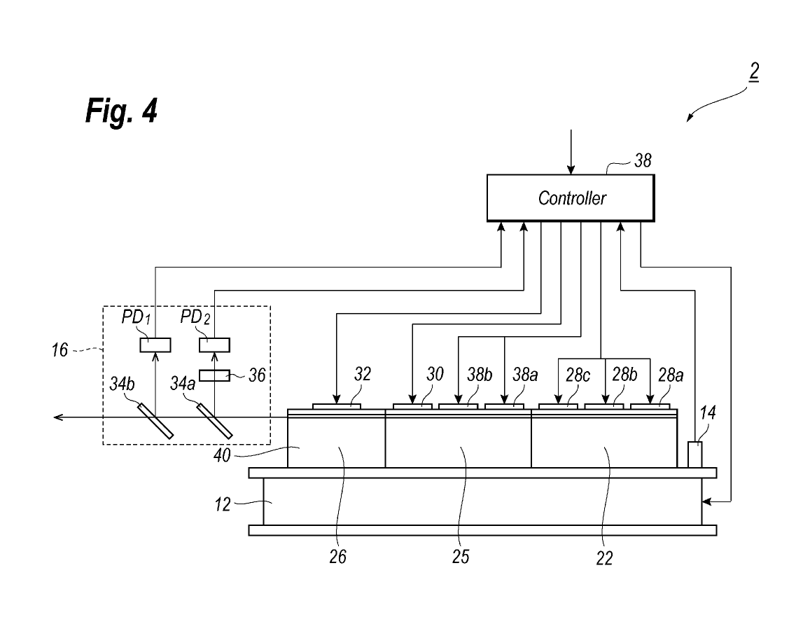

FIG. 4 schematically illustrates an apparatus 2 including a tunable laser diode (LD) 40 with an intelligent controller 38 according to the second embodiment of the invention. The apparatus 2 also includes a TEC 12 mounting the tunable LD 40 thereon, a thermistor 14 to sense the temperature of the LD 40, a wavelength locker 16, and the controller 38. The wavelength locker 16, the TEC 12, and the thermistor 14 have respective function same as those of the first embodiment shown in FIG. 1. A feature of the present embodiment is that the SG-DFB 25 in the tunable LD 40 provides a plurality of heaters.

Specifically, the waveguide in the SG-DFB 25 provides a plurality of gratings each apart by a preset span; and, from another view point, the waveguide also includes a plurality of gain regions and a plurality of tune regions alternately arranged to each other along the optical axis thereof. The SG-DFB 25 also shows a plurality of gain peaks with a substantially constant span.

A feature different from that of the first embodiment is the tune regions of the present embodiment each provides a heater to adjust a temperature of the waveguide not the electrode to inject carrier therein. The present embodiment provides two electrodes, 38a and 38b, to supply electrically power to the heater in addition to the electrode 30. Similar to the heaters provided in the CSG-DBR 22, the heater in the SG-DFB 25 adjusts the temperature of the waveguide, which modifies the refractive index thereof and the gain spectrum of the SG-DFB 25, specifically the peak wavelength in the gain spectrum.

Even when the number of heaters is increased, the controller, 18 or 38, may switch the emission wavelength and the optical output power promptly responding to the external instruction. The second embodiment provides two additional heaters compared with the first embodiment. In an ordinary state, the controller 38 monitors all conditions of the apparatus 2 evenly, while, triggered by the external instruction, the controller 38 changes the sensing mode from the ordinarily sensing mode 1 to the quick sensing mode 2 or 3. The controller 38 senses totally 14 conditions including the voltages each applied to five heaters, the ground level of the heaters, and two photocurrents of the PDs, PD₁ and PD₂. While, the controller 38 omits the monitoring for 5 conditions of not affecting the emission wavelength, and monitors only 8 conditions. Thus, the sampling rate of the A/D-C is increased by 1.75 times to that in the sensing mode 1. The controller 38 may also switch the mode from the sensing mode 1 to the sensing mode 3, where the conditions affecting the emission wavelength and the optical output power are regularly sensed but rest conditions are intermittently monitored. Then, the sampling rate for the conditions affecting the emission wavelength and the optical output power may be equivalently increased.

In the foregoing detailed description, the apparatus and the sequence of the present invention have been described with reference to specific exemplary embodiments thereof. It will, however, be evident that various modifications and changes may be made thereto without departing from the broader spirit and scope of the present invention. The present specification and figures are accordingly to be regarded as illustrative rather than restrictive.

What is claimed is:

1. A method to control an emission wavelength of a tunable laser diode (LD) digitally, the tunable LD providing a reflective portion showing a plurality of reflection peaks and a gain portion showing a plurality of gain peaks, the emission wavelength being set in a wavelength at which one of reflection peaks and one of gain peaks coincide to each other, the method including steps of:
evenly monitoring conditions of the reflective portion, the gain portion, and ambient conditions of the tunable LD;
receiving an external instruction to switch the emission wavelength; and
triggered by the external instruction, monitoring the conditions only of the reflective portion and the the gain portion that affect the emission wavelength.

2. The method of claim 1,
wherein the monitoring of the conditions only of the reflective portion and the gain portion continues until the switched emission wavelength becomes stable.

3. The method of claim 1,
wherein the monitoring of the conditions of the reflective portion, the gain portion and the ambient conditions is carried out by a single analog-to-digital converter (A/D-C).

4. The method of claim 1,
wherein the tunable LD further includes a semiconductor optical amplifier, and
wherein the monitoring of the conditions triggered by the external instruction further includes monitoring conditions of the semiconductor optical amplifier that affects an optical output power of the tunable LD.

5. The method of claim 1,
wherein the reflective portion includes a heater and the gain portion includes a tune region whose refractive index is modified by a current injected therein, and
wherein the monitoring of the conditions triggered by the external instruction includes monitoring electrical power supplied to the heater in the reflective portion and the current injected into the tune region in the gain portion.

6. The method of claim 5,
wherein the tunable LD further includes a semiconductor optical amplifier, and
wherein the monitoring of the conditions triggered by the external instruction further includes monitoring conditions of the semiconductor optical amplifier.

7. The method of claim 1,
wherein the reflective portion includes a heater and the gain portion includes a tune region with a heater, and
wherein the monitoring of the conditions triggered by the external instruction includes monitoring electrical power supplied to the heater in the reflective portion and electrical power supplied to the heater in the tune region of the gain portion.

8. The method of claim 7,
wherein the tunable LD further includes a semiconductor optical amplifier, and
wherein the monitoring triggered by the external instruction further includes monitoring conditions of the semiconductor optical amplifier.

9. A method to control an emission wavelength of a tunable laser diode (LD) digitally, the tunable LD providing a reflective portion showing a plurality of reflection peaks and a gain portion showing a plurality of gain peaks, the emission wavelength being set in a wavelength at which one of reflection peaks and one of gain peaks coincide to each other, the method including steps of:
evenly monitoring conditions of the reflective portion, the gain portion, and ambient conditions of the tunable LD;
receiving an external instruction to switch the emission wavelength; and
triggered by the external instruction, regularly monitoring conditions of the reflective portion and conditions of the the gain portion that affect the emission wavelength of the tunable LD, but intermittently monitoring the ambient conditions independent of the emission wavelength.
